(19) United States
(12) Patent Application Publication
(10) Pub. No.: US 2007/0120263 A1
(43) Pub. Date: May 31, 2007

(54) Conductor track arrangement and associated production method

(76) Inventors: Zvonimir Gabric, Zorneding (DE); Werner Pamler, Muenchen (DE); Guenther Schindler, Muenchen (DE); Andreas Stich, Gruenwald (DE)

Correspondence Address: BRINKS HOFER GILSON & LIONE, P.O. BOX 10395, CHICAGO, IL, 60610, US

(21) Appl. No.: 11/506,570

(22) Filed: Aug. 18, 2006

(30) Foreign Application Priority Data
Aug. 19, 2005 (DE) 10 2005 039 323.3

(51) Int. Cl. H01L 23/48

(52) U.S. Cl. 257/762

(57) ABSTRACT

A conductor track arrangement includes a substrate, at least two conductor tracks, a cavity and a resist layer that covers the conductor tracks and closes off the cavity. By forming carrier tracks with a width less than a width of the conductor tracks, air gaps can also be formed laterally underneath the conductor tracks for reducing the coupling capacitances and the signal delays in a self-aligning manner.

### PRIORITY CLAIM

The present application claims the benefit of priority of German Patent Application No. DE 10 2005 039 323.3, filed Aug. 19, 2005, the contents of which are incorporated by reference herein.

### TECHNICAL FIELD

The present invention relates to a conductor track arrangement and an associated production method and, in particular, to a conductor track arrangement with cavities or so-called “air gaps.”

### BACKGROUND

Conductor track arrangements are used, in particular, in semiconductor technology for implementing the wiring of semiconductor components. In this arrangement, a dielectric layer or insulating layer is usually formed on an electrically conductive carrier substrate such as, for example, a semiconductor substrate, and on this an electrically conductive conductor track layer is formed, the conductor track layer, after patterning, representing the final conductor track. Following that, further insulating layers and electrically conductive layers are formed successively which results in a stack of layers which also provides for complex wiring patterns by using so-called “vias.”

The electrical characteristics of the conductor track arrangement depend significantly on the materials used and, in particular, on the electrical conductivity of the conductor tracks and on parasitic capacitances per area section or length section of the conductor track.

With increasing packing density of integrated semiconductor circuits, the conductor tracks formed in the metallization levels also have an ever decreasing spacing from one another. Apart from the aforementioned increase in capacitances between the conductor tracks, this also leads to an increase in signal delays, power dissipation and crosstalk in the semiconductor chip. When SiO2 is used as dielectric between the conductor tracks, the dielectric constant k of which is about 3.9 and represents a reference value, these problems are normally solved by optimizing the wiring layout of the conductor tracks.

From U.S. Pat. No. 5,461,003A, a conductor track arrangement is known in which air gaps are used for reducing a capacitive coupling between adjacent conductor tracks, using a porous dielectric resist layer for removing a sacrificial layer needed for the air gap while at the same time ensuring adequate mechanical stability.

From DE 101 407 54 A1, a conductor track arrangement and an associated production method are also known in which a multiplicity of air gaps are formed and arranged in the form of trenches between or above respective conductor tracks in order to reduce such coupling capacitances, power losses and crosstalk.

The disadvantageous factor, however, is that the known production methods are extremely complex and thus cost-intensive, and the completed conductor track arrangement has poor mechanical stability. Furthermore, the reduction in coupling capacitances is not optimal. Furthermore, a susceptibility to short circuits of adjacent conductor tracks can be observed in the case of electromigration.

### BRIEF SUMMARY

A conductor track arrangement and an associated production method is disclosed wherein the coupling capacitances are reduced further and the mechanical and electrical characteristics are improved.

Additional cavities or “air gaps”, which considerably reduce parasitic coupling capacitances and the crosstalk etc., while providing high mechanical stability, are also created laterally below the conductor tracks, in particular by forming dielectric carrier tracks underneath the conductor tracks, a width of the conductor tracks being greater than a width of the carrier tracks.

With regard to the method, the dielectric carrier tracks are formed in a self-aligning manner from a carrier layer by using the conductor tracks as a mask, whereby a conductor track arrangement improved in this manner can be implemented in a particularly cost-effective manner without additional masks.

An insulating layer is preferably formed on the surface of the conductor tracks, on the surface of the carrier tracks and on the surface of the substrate or on the surface of the carrier layer, respectively, toward the cavity, as a result of which short circuits between adjacent conductor tracks, caused by electromigration, can be considerably reduced. In this context, on the one hand, this insulating layer covering the exposed surfaces of the conductor track at least impedes an out-diffusion of conductor track material in the cavity, occurring due to electromigration processes. In particular, however, such an insulating layer prevents a short circuit between adjacent conductor tracks caused by this process.

This insulating layer is preferably formed in one piece with a resist layer which covers the conductor tracks and closes off or seals the cavity. This further simplifies the production method and reduces costs.

The production method performed is, in particular, a non-conformal CVD deposition process with SiH₄ and N₂O in the ratio of SiH₄:N₂O=1:5 to 1:20 at a pressure of 1 to 10 torr (133 to 1333 Pa), a temperature of 350 to 450 degrees Celsius and an RF power of 200 to 400 watts. With this special deposition process and the associated parameters, the insulating layer described above can be formed with high quality on all exposed surfaces of the conductor tracks whereas the cavities between the conductor tracks are covered or sealed toward the top at the same time. This further reduces production costs with improved electric characteristics.

The substrate can preferably also precisely specify an etch barrier for determining a depth of the undercut part-cavity which allows the process to be better controlled. As an alternative, however, a corresponding predetermined etch depth can be set even without such an etch barrier but by monitoring a predetermined etching time. In this manner, a conductor track arrangement with self-aligning support structures can be produced cost-effectively without using additional lithographic steps and with good mechanical stability.

Other systems, methods, features and advantages of the invention will be, or will become, apparent to one with skill in the art upon examination of the following FIGures and detailed description. It is intended that all such additional systems, methods, features and advantages be included within this description, be within the scope of the invention, and be protected by the following claims.

### BRIEF DESCRIPTION OF THE DRAWINGS

The invention can be better understood with reference to the following drawings and description. The components in the FIGures are not necessarily to scale, emphasis instead being placed upon illustrating the principles of the invention. Moreover, in the FIGures, like referenced numerals designate corresponding parts throughout the different views.

FIGS. 1A to 1D show sectional views for illustrating steps during the production of a conductor track arrangement.

FIGS. 2A to 2D show simplified sectional views for illustrating steps during the production of a conductor track arrangement.

### DETAILED DESCRIPTION

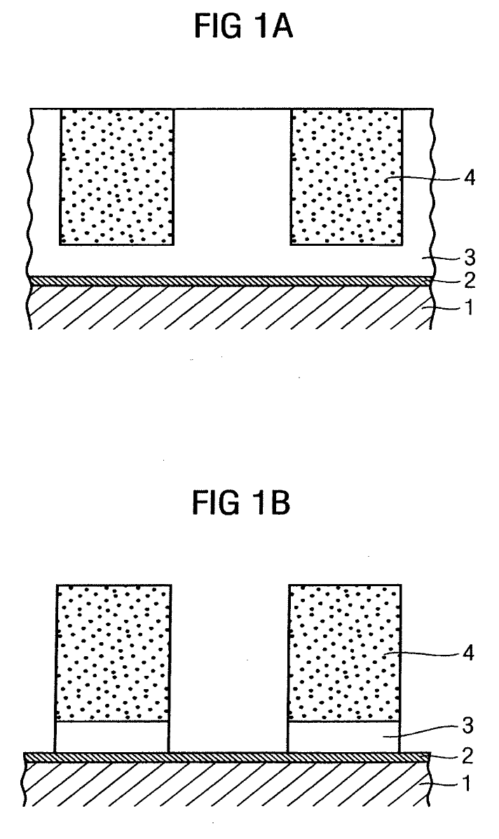

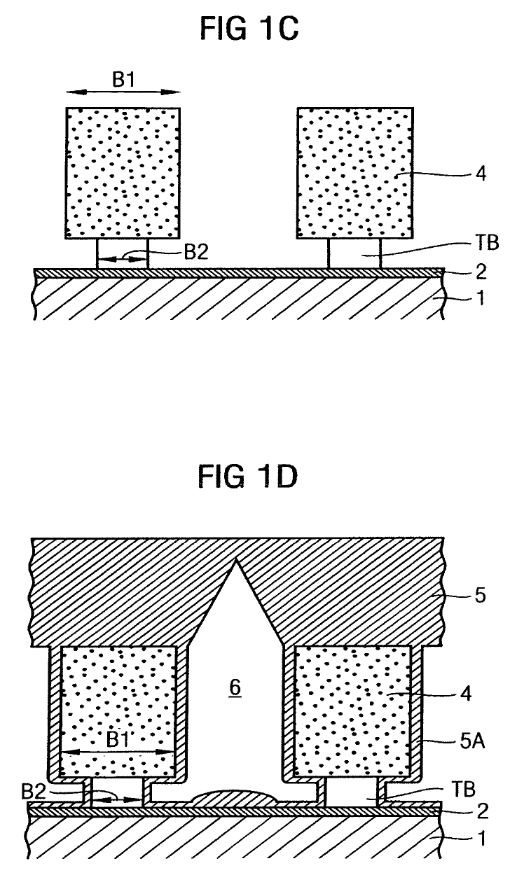

FIGS. 1A to 1D show sectional views for illustrating steps during the production of a conductor track arrangement according to a first exemplary embodiment, performing a “damascene process” for forming the conductor tracks.

The disclosure shows a first metallization level, i.e., a lowermost conductor track level which is located in the immediate vicinity of the semiconductor substrate, not shown, since the extent of the cavities according to the disclosure laterally underneath the conductor tracks, in particular, leads to a reduction of the coupling capacitances of the conductor tracks to a semiconductor substrate lying underneath or to conductor tracks lying underneath.

According to FIG. 1A, a conductor track pattern of conductor tracks 4 is formed by a damascene process in a dielectric substrate. The substrate according to the first exemplary embodiment can have a first dielectric or a first dielectric layer 1, an etch barrier 2 formed thereon and a second dielectric or a second dielectric layer 3 formed on the etch barrier 2. In principle, other materials, and particularly silicon and/or metals, can also be used for these layers 1, 2 and 3. This sequence of layers may be located as intermediate dielectric between the semiconductor substrate (not shown) and a first metallization level or between respective metallization levels.

For the first and second dielectric 1 and 3, SiO₂ is used, for example, and a Si₃N₄ layer can be used as etch barrier 2. As an alternative, low-k dielectrics, which have a lower dielectric constant of, e.g., k=1 to 3.9 with respect to the SiO₂ considered as reference value, can also be used for the dielectrics 1 and 3. Similarly, alternative layers which again have a reduced dielectric constant with reference to Si₃N₄ can also be used as an alternative to the preferred Si₃N₄ etch barrier 2. When such low k dielectrics are used, the parasitic coupling capacitances may be considerably reduced. In the low k dielectrics, carbon-containing or fluorine-containing compounds are particularly advantageous, for example. In this case, for example, SiO₂, SiC or SiCN could be used instead of nitride for implementing the etch barrier 2. Alternative combinations of materials can also be used for the dielectrics and the etch barrier.

Using a conventional damascene process (or dual damascene process), a multiplicity of conductor track patterns or the conductor tracks 4, respectively, are now formed in the topmost, i.e. second dielectric layer 3. After forming trenches in the second dielectric layer 3, a barrier layer (not shown) is preferably deposited first on the surface of the trenches, e.g. by PVD, CVD or ALD methods, in order to prevent out-diffusion of conductor track material of the conductor track 4, particularly into the semiconductor substrate. Following this, a seed layer (not shown), which facilitates the deposition of the actual conductor track material, can be formed preferably by sputtering on the surface of the barrier layer. Finally, the actual conductor track material is formed on the seed layer or directly on the barrier layer and the trench is completely filled. After a planarization step such as, for example, a Chemical Mechanical Polishing (CMP) process, the sectional view shown in FIG. 1A is obtained.

When Cu is used as conductor track material for the conductor tracks 4, a plating process and, in particular, an electrical plating process, for example, can be used for depositing the conductor track material in the trench. When copper (Cu) is used as conductor track material, a sequence of layers TaN/Ta provides a barrier layer. As an alternative, however, tungsten (W) can also be used as conductor track material, a CVD process preferably being used for filling the trenches and a layer sequence of Ti/TiN being used as seed layer. Naturally, alternative materials could also be used again for the seed layer, barrier layer or the conductor track material.

Furthermore, a barrier layer (not shown), e.g. CoWP or NiMoP, could be preferably selectively deposited as resist layer on the exposed surface of the conductor track 4, for example after the planarization step, to also prevent out-diffusion of conductor track material out of this upper surface into the adjacent layers and, in particular, into the semiconductor substrate.

A depth of the trenches formed in the damascene process, or a distance of the trench bottom from the etch barrier 2 defines a height of the air gap according to the disclosure, additionally formed, and thus the parasitic coupling capacitances.

According to FIG. 1B, the second dielectric 3 is then removed by an anisotropic etching process between the conductor tracks 4 up to the etch barrier 2. Accordingly, the conductor tracks 4 and their barrier layers, respectively, are no longer covered by the second dielectric 3 on the side and are standing freely on the dielectric strip remaining underneath the conductor tracks 4. The anisotropic, i.e. directed etching processes performed can be, for example, dry etching processes and, in particular, reactive ion etching (RIE). According to FIG. 1B, an initially still equally wide dielectric support structure 3 is formed accordingly without additional lithographic step and only by using the conductor track 4 as a mask.

According to FIG. 1C, the remaining support dielectric 3 underneath the conductor tracks 4 is then diminished by an isotropic etching process, i.e. a random etching process such as, for example, a wet chemical (HF) etching or an isotropic dry etching process, in such a manner that a width B1 of the conductor tracks 4 is greater than a width B2 of the dielectric carrier tracks TB formed underneath. The width B2 is preferably less than or equal to half the width B1 of the conductor tracks 4 which results in a sufficiently large air gap laterally underneath the conductor tracks 4 to reduce the capacitance. If the width B2 of the carrier tracks is approx. ½ B1 of the conductor tracks 4, sufficiently high mechanical strength of the conductor track arrangement is additionally obtained for a semiconductor chip produced later.

According to FIG. 1C, the spaced-apart conductor tracks 4 now stand on very narrow fins or, respectively, the dielectric carrier tracks TB which stand on the etch barrier 2 and the first dielectric 1 lying underneath. The particular advantage of this method can be seen in the fact that, particularly in contrast to conventional methods, these support structures or carrier tracks TB can be formed in a self aligning manner without using additional masks or lithographic steps by using only the conductor tracks 4 as a mask which are already present. Since, in addition, the etching processes used essentially represent standard etching processes, the conductor track arrangement according to the disclosure can be implemented in a particularly simple and cost-effective manner.

According to FIG. 1D, a resist layer 5 is now formed in a concluding step in such a manner that it completely covers the conductor tracks 4 and generates, or closes off, respectively, a cavity 6 existing between the conductor tracks 4. To implement this resist layer 5, conventional non-conformal CVD deposition processes can be used, in principle, by which, for example, a silicon oxide layer can be deposited over the entire area and the cavities 6 are created and sealed. As an alternative, a selective deposition process for depositing a selective oxide such as, e.g., O₃/TEOS can also be performed. Another possibility for implementing the resist layer 5 consists in spinning on a sufficiently tough spin-on glass which does not penetrate into the cavity 6. Such deposition processes preferably take place in air, vacuum or an electrically insulating gas which results in a filling with air, vacuum or an electrically insulating gas for the cavity 6 which has particularly low dielectric constants.

According to the disclosure, however, a special non conformal CVD deposition process can be applied in which an oxide insulating layer 5A can be additionally formed on the surface of the conductor tracks 4 or the barrier layers (not shown), the carrier tracks TB and the substrate lying underneath, or the etch barrier 2, respectively. This insulating layer 5A is preferably formed in the same deposition process as an oxide resist layer 5 as a result of which a further simplification of the method can be achieved.

For the simultaneous implementation of this thin insulating layer 5A and the relatively thick resist layer 5, for example, SiH₄ and N₂O is deposited in the ratio of SiH₄:N₂O=1:5 to 1:20 at a process temperature of 350 to 450 degrees Celsius, a process pressure of 1 to 10 torr (133 to 1333 Pa) and an RF power of 200 to 400 watts.

As an alternative to simultaneously forming the insulating layer 5A and the resist layer 5, a two-stage process is also possible. In this case, conformal, i.e. equally thick 0₃/TEOS is first formed as an insulating layer 5A over the entire area, i.e. also in the cavity 6 and then the non-conformal resist layer 5 is produced by one of the processes described above. As a result, a sufficiently thick and protective insulating layer 5A, which exhibits considerable advantages particularly in the electromigration processes mentioned initially, can be formed even on the undersides of the conductor tracks 4 exposed in the preceding process steps. Electromigration processes are understood to be processes, particularly in metallic conductor tracks, wherein conductor track material is transported due to current flow in such a manner that conductor track material is displaced within the conductor tracks.

The insulating layers 5A now represent a certain impediment against such electromigration phenomena and can thus at least impede the migration of conductor track material occurring especially at edges and corners. An out-diffusion of conductor track material, which can usually be observed, out of the areas originally provided for the conductor tracks 4 into the cavities 6 can thus be prevented at least conditionally. In particular, however, the additional insulating layer 5A prevents a short circuit between two adjacent conductor tracks, which can usually be observed, due to electromigration.

Thus, if the conductor track material is diffused from a conductor track into the cavity 6 due to electromigration and has led to a local accumulation of material but the oppositely adjacent conductor track does not exhibit such a breakthrough, the insulating layer 5A of the adjacent conductor track 4 reliably prevents an unwanted short circuit. This provides a conductor track arrangement which has not only reduced coupling capacitances, and thus reduced signal delay and improved crosstalk behavior, but also has improved electromigration characteristics, particularly in long-term operation.

According to FIG. 1D, the cavity 6 formed by the resist layer 5 has in its lower area a widening which is essentially determined by the spacing of the carrier tracks TB. In its center area, the width of the cavity 6 is essentially determined by the spacing of the conductor tracks 4. In its upper area, the cavity 6 has a taper due to the non-conformal deposition process. Such a shape of the cavity 6 has a particularly advantageous effect on reducing the parasitic coupling capacitances.

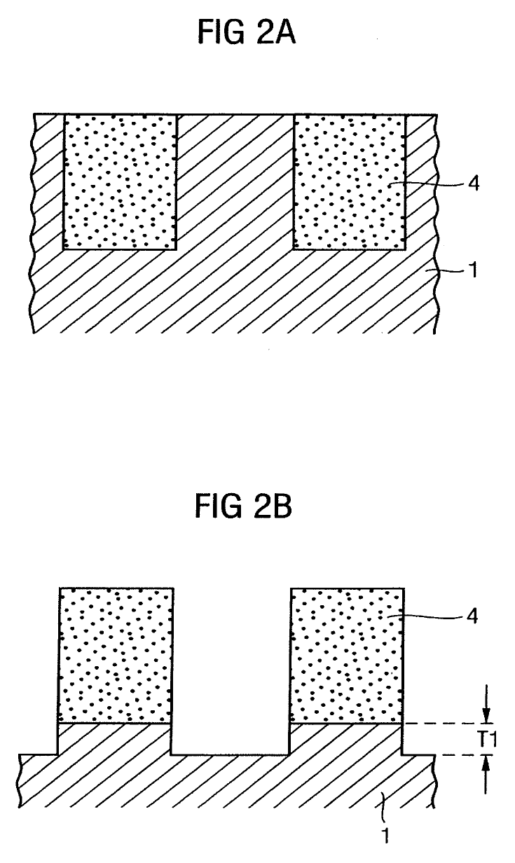

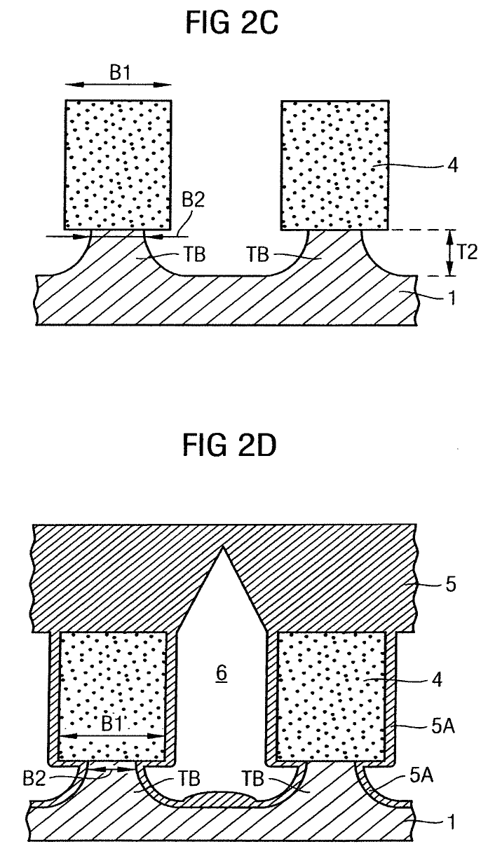

FIGS. 2A to 2D show sectional views for illustrating steps during the production of a conductor track arrangement according to a second exemplary embodiment, the substrate not having an etch barrier in contrast to the first exemplary embodiment.

According to FIG. 2A, accordingly, only a first dielectric 1 is formed as substrate, for example on a semiconductor substrate, not shown, or an underlying metallization level and a multiplicity of conductor tracks 4 are produced therein by a conventional damascene process. To avoid repetitions, reference is made to the description of the first exemplary embodiment according to FIGS. 1A to 1D with respect to the damascene process and the dielectric used and the composition of the conductor tracks 4.

According to FIG. 2B, a directed etching process or anisotropic etching, respectively, can again be performed for exposing the side areas of the conductor tracks 4 and for forming a deepening in the dielectric 1 up to a depth Ti as in the first exemplary embodiment according to FIGure 1D. The depth TI in the dielectric 1 is preferably determined by a predetermined duration of the etching process.

According to FIG. 2C, isotropic etching back for diminishing the dielectric 1 underneath the conductor tracks 4 is again performed comparably to the first exemplary embodiment according to FIG. 1C, which essentially corresponds to a self-aligning forming of the carrier tracks TB by using the conductor tracks 4 as a mask. As in the first exemplary embodiment, wet chemical etching processes such as, e.g., HF etching processes or isotropic dry etching processes can again be performed for carrying out this isotropic etching process. In this further etching process, circular underetchings are essentially produced at the side edges underneath the conductor tracks with a second depth T2 in the dielectric 1 which reduce an additional cavity or air gap for reducing the parasitic coupling capacitances, particularly in the direction of a semiconductor substrate.

A width B1 of the conductor tracks is again greater, at least at the contact area between conductor track 4 and dielectric 1, than a width B2 of the carrier tracks TB which are now formed to be mesa-shaped. As in the first exemplary embodiment, the side walls of the carrier tracks TB are preferably spaced apart equally from the side walls of the associated conductor tracks 4 as a result of which a certain symmetry of the parasitic effects can be achieved.

Finally, according to FIG. 2D, a resist layer 5 is again formed on the surface of the conductor tracks 4 as a result of which the cavities 6 are formed between the conductor tracks 4 and are sealed. An insulating layer 5A can also be formed again on the surface of the conductor tracks 4, of the carrier tracks TB and of the dielectric 1 as a result of which the electromigration phenomena described above are reduced.

Furthermore, the non conformal CVD deposition process described above, with its special parameters for simultaneously forming the insulating layer 5A and the resist layer 5, can be performed.

According to a third exemplary embodiment, not shown, instead of the anisotropic and isotropic etching process performed in FIGS. 2B and 2C, only an isotropic etching process can also be performed for exposing the side areas of the conductor tracks 4 and for implementing the air gaps or etchings out underneath the side edges of the conductor tracks 4 for forming the carrier tracks TB with a width B2 reduced compared with the conductor track 4, as a result of which the method can be simplified further.

According to a further fourth exemplary embodiment, not shown, a subtractive process, such as is known, for example, from conventional A1 conductor track technology, can also be performed instead of the damascene process shown in FIGS. 1 and 2. In this process, a conductor track layer which preferably has A1 is formed over the entire area on the surface of a substrate (with or without etch barrier 2), and is then photolithographically patterned as a result of which the conductor tracks can be produced. The method according to the invention can then be completed in accordance with the exemplary embodiments of 1B to 1D or 2B to 2D as a result of which a conductor track arrangement with minimal coupling capacitances and thus reduced signal delays is again obtained. In addition, the mechanical stability and the sensitivity to electromigration phenomena are greatly improved so that the service life is greatly increased.

The disclosure has been described above by a semiconductor substrate as the basic carrier substrate. However, it is not restricted to this and similarly also comprises other conductive or non-conductive carrier materials.

It is therefore intended that the foregoing detailed description be regarded as illustrative rather than limiting, and that it be understood that it is the following claims, including all equivalents, that are intended to define the spirit and scope of this invention.

1. A conductor track arrangement comprising
a substrate;
at least two conductor tracks formed next to one another above the substrate;
a cavity formed substantially at least between the conductor tracks; and
a dielectric resist layer, wherein the dielectric resist layer covers the conductor tracks and substantially closes off the cavity, wherein carrier tracks are formed between the substrate and the conductor tracks that carry the conductor tracks, and a width of the conductor tracks is greater at their contact area than a width of the carrier tracks.

2. The conductor track arrangement of claim 1, wherein side walls of the carrier tracks are spaced apart substantially equally with respect to side walls of associated conductor tracks.

3. The conductor track arrangement of claim 1, further comprising an insulating layer formed on a surface of the conductor tracks, on a surface of the carrier tracks and on a surface of the substrate with respect to the cavity.

4. The conductor track arrangement of claim 3, wherein the insulating layer comprises a conformal O3/TEOS layer and the resist layer comprises a non-conformal oxide layer.

5. The conductor track arrangement of claim 3, wherein the insulating layer and the resist layer are formed in one piece.

6. The conductor track arrangement of claim 1, wherein the substrate comprises an etch barrier formed on an intermediate dielectric.

7. The conductor track arrangement of claim 6, wherein the etch barrier comprises at least one of SiC and Si₃N_{4.}

8. The conductor track arrangement of claim 7, wherein the carrier tracks are formed in parallel with the conductor tracks.

9. The conductor track arrangement of claim 1, wherein the cavity has a widening in a lower area and a taper in an upper area.

10. The conductor track arrangement of claim 1, wherein the conductor tracks comprise a barrier layer that prevents an out-diffusion of conductor track material.

11. The conductor track arrangement of claim 1, wherein the cavity is filled with air, vacuum or an electrically non-conductive gas, the conductor tracks have Cu or A1 as conductor track material, and the carrier tracks have at least one of SiO₂ and a low-k material.

12. A method that produces a conductor track arrangement, comprising:
forming conductor tracks on a substrate;
forming carrier tracks from the substrate by using the conductor tracks as a mask, a width of the conductor tracks being greater than a width of the carrier tracks; and
forming a dielectric resist layer which covers the conductor tracks and closes off a cavity between the conductor tracks.

13. The method of claim 12, wherein forming conductor tracks comprises forming the conductor tracks by a subtractive process or by a damascene process.

14. The method claim of 12, wherein the substrate has a first dielectric, an etch barrier and a second dielectric, further comprising removing the exposed second dielectric up to the etch barrier by anisotropic etching.

15. The method of claim 12, wherein the substrate only has a first dielectric, further comprising removing the exposed first dielectric up to a predetermined depth by anisotropic etching.

16. The method of claim 12, wherein forming carrier tracks comprises performing an isotropic etch back for self-aligned diminishing of the dielectric underneath the conductor tracks.

17. The method of claim 16, wherein performing an isotropic etch back comprises performing wet etching or isotropic dry etching.

18. The method of claims 12, wherein forming a dielectric resist layer comprises forming an insulating layer simultaneously with the resist layer on a surface of the conductor tracks, on a surface of the carrier tracks, and on a surface of the substrate.

19. The method of claim 17, further comprising performing a non-conformal CVD deposition process with SiH4 and N2O in a ratio of SiH₄:N₂O=1:5 to 1:20 at a pressure of 1 to 10 torr (133 to 1333 Pa), a temperature of 350 to 450 degrees Celsius and an RF power of 200 to 400 watts.

20. The method of claim 12, wherein forming a dielectric resist layer comprises forming the resist layer by using air, vacuum or an electrically non-conductive gas.

21. A conductor track arrangement, comprising:
means for forming conductive tracks on a substrate;
means for forming carrier tracks from the substrate; and
means for forming an insulating layer which covers the conductor tracks and closes off a cavity between the conductor tracks.

22. The conductor track arrangement of claim 21, wherein the means for forming conductive tracks comprises means for forming the conductive tracks by a subtractive process or by a damascene process.

23. The conductor track arrangement claim 21, wherein the substrate has a first dielectric, an etch barrier and a second dielectric, further comprising means for removing the exposed second dielectric up to the etch barrier.

24. The conductor track arrangement of claim 21, wherein the substrate only has a first dielectric, further comprising means for removing the exposed first dielectric up to a predetermined depth.

25. The method of claim 21, wherein the means for forming carrier tracks comprises means for performing an isotropic etch back for self-aligned diminishing of the dielectric underneath the conductor tracks.

26. The method of claim 25, wherein the means for performing an isotropic etch back comprises means for performing wet etching or isotropic dry etching.

27. The conductor track arrangement of claim 26, further comprising means for performing a non-conformal CVD deposition process.

28. The conductor track arrangement of claim 21, wherein the means for forming an insulating layer is conFIGured to form the resist layer by using air, vacuum or an electrically non-conductive gas.
